(19) United States
(12) Patent Application Publication
(10) Pub. No.: US 2026/0060096 A1
(43) Pub. Date: Feb. 26, 2026

(54) SEMICONDUCTOR WAFER STRUCTURE

(71) Applicant: SAMSUNG ELECTRONICS CO., LTD., SUWON-SI (KR)

(72) Inventors: Yeongkwon Ko, Suwon-si (KR); Unbyoung Kang, Suwon-si (KR); Kuyoung Kim, Suwon-si (KR); Junyeong Heo, Suwon-si (KR)

(21) Appl. No.: 19/055,685

(22) Filed: Feb. 18, 2025

(30) Foreign Application Priority Data
Aug. 22, 2024 (KR) 10-2024-0113022

(51) Int. Cl. H01L 23/544; H01L 23/00; H01L 23/48

(52) U.S. Cl. CPC H01L 23/544; H01L 23/481; H01L 24/06; H01L 2223/54426; H01L 2224/06181

(57) ABSTRACT

A wafer structure includes a semiconductor substrate including chip regions and a scribe region for separating each of chip regions, an interlayer insulating layer on the first surface of the semiconductor substrate, an upper insulating layer on the interlayer insulating layer, connection structures formed within the chip regions and partially surrounded by the interlayer insulating layer and the upper insulating layer respectively. First to third trenches formed within the scribe region, and extending along a first side of the scribe region and penetrating the upper insulating layer and the interlayer insulating layer, and dummy structures disposed between the first trench and the third trench and between the second trench and the third trench and partially surrounded by the interlayer insulating layer and the upper insulating layer respectively.

### CROSS-REFERENCE TO RELATED APPLICATION

This application claims priority under 35 U.S. C. § 119 of Korean Patent Application No. 10-2024-0113022 filed on Aug. 22, 2024 in the Korean Intellectual Property Office, the entire disclosure of which is incorporated by reference herein in its entirety.

### BACKGROUND

The present inventive concept relates to a semiconductor wafer structure.

A semiconductor wafer structure on which an integrated circuit is formed and is separated into individual chips using a sawing process. For separating the individual chips from the semiconductor wafer structure, a sawing process such as blade dicing, laser dicing, and plasma dicing, or a combination thereof may be performed on the wafer structure. However, some dicing methods may not be applied to the sawing process due to thin thickness of the semiconductor wafer structure.

### SUMMARY

Example embodiments provide a semiconductor wafer structure to which various types of sawing processes are applicable.

According to example embodiments, a wafer structure includes, a semiconductor substrate having a first surface on which individual devices are formed and a second surface opposite to the first surface, and including chip regions and a scribe region for separating each of chip regions, an interlayer insulating layer on the first surface of the semiconductor substrate, an upper insulating layer on the interlayer insulating layer, connection structures formed within the chip regions and partially surrounded by the interlayer insulating layer and the upper insulating layer respectively, a first trench formed within the scribe region, and extending along a first side of the scribe region and penetrating the upper insulating layer and the interlayer insulating layer, a second trench formed within the scribe region, and extending along a second side of the scribe region and penetrating the upper insulating layer and the interlayer insulating layer, a third trench formed within the scribe region, and extending along between the first trench and the second trench and penetrating the upper insulating layer and the interlayer insulating layer; and dummy structures disposed between the first trench and the third trench and between the second trench and the third trench, and partially surrounded by the interlayer insulating layer and the upper insulating layer respectively.

According to example embodiments, a wafer structure includes a semiconductor substrate including chip regions and a scribe region between the chip regions, a device layer disposed on the semiconductor substrate and the device layer including dummy structures within the scribe region, a plurality of trenches disposed within the device layer and the plurality of trenaches including a pair of trenches spaced apart from each other in a first direction and extending into a second direction which is perpendicular to the first direction within the scribe region and a central trench disposed between the pair of trenches and extending into the second direction, and a passivation layer disposed on the device layer and filling at least a portion of each of the plurality of trenches, wherein the dummy structures are positioned between the plurality of trenches.

According to example embodiments, a wafer structure includes a semiconductor substrate including chip regions and a scribe region defining the chip regions, a device layer including connection structures disposed within the chip regions, dummy structures within the scribe region, and an interlayer insulating layer surrounding the connection structures and the dummy structures, a plurality of trenches disposed within the scribe region and penetrating the interlayer insulating layer in which the plurality of trenches include a first trench and a second trench disposed along the first and second sides of the scribe region respectively, and a third trench disposed between the first trench and the second trench, and the dummy structures are disposed between the plurality of trenches, wherein, when the wafer structure have a first thickness, the first and second trenches are configured to perform a sawing process upon the first and second trenches with a first dicing method and, when the wafer structure have a second thickness, to perform a sawing process upon the third trench with a second dicing method, and the first thickness and the second thickness are different each other and the first dicing method and the second dicing method.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a perspective view of a wafer structure according to an example embodiment, and FIG. 1B is a partial enlarged view of an area ‘A’ of FIG. 1A.

FIGS. 2A to 2C are partial enlarged views of wafer structures according to example embodiments.

FIGS. 3A to 3D are partial enlarged views illustrating a manufacturing process of a wafer structure of FIG. 2C.

FIG. 4 is a partial enlarged view of a wafer structure according to an example embodiment.

FIGS. 5A to 5C are partial enlarged views illustrating a manufacturing process of the wafer structure of FIG. 4.

FIG. 6 is a perspective view of a wafer structure of an example embodiment to which a sawing process is applied.

FIGS. 7A and 7B are partial enlarged views of wafer structures of example embodiments to which a sawing process is applied.

FIGS. 8A and 8B are cross-sectional views of semiconductor packages including individual chips separated from wafer structures.

FIG. 9 is a cross-sectional view of a semiconductor package including individual chips separated from wafer structures.

### DETAILED DESCRIPTION OF THE EMBODIMENTS

Hereinafter, with reference to the accompanying drawings, example embodiments of the present inventive concept will be described. Unless otherwise specified, terms such as “upper portion,” “upper surface,” “lower portion,” “lower surface,” “side,” “side surface” and the like are based on the drawings, and may vary depending on the direction in which the components are disposed.

Additionally, ordinal numbers such as “first,” “second,” and “third” may be used as labels for specific devices, steps, and directions to distinguish various devices, steps, and directions from each other. Terms that are not described using “first,” and “second” in the specification may still be referred to as “first” or “second” in the claims. Additionally, terms referenced by a particular ordinal number may be described elsewhere with a different ordinal number. For example, the term “first” in a particular claim may be described as the term “second”in the specification or another claim.

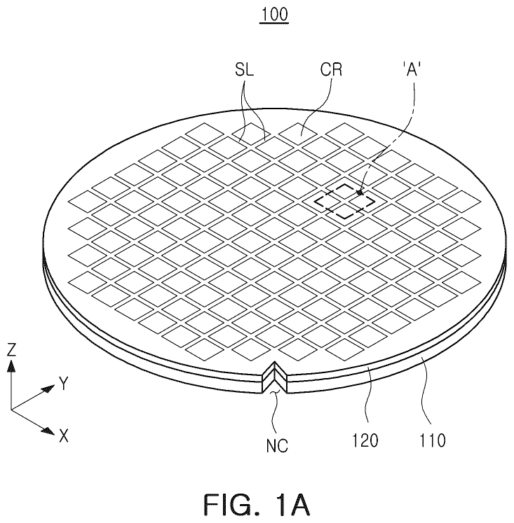

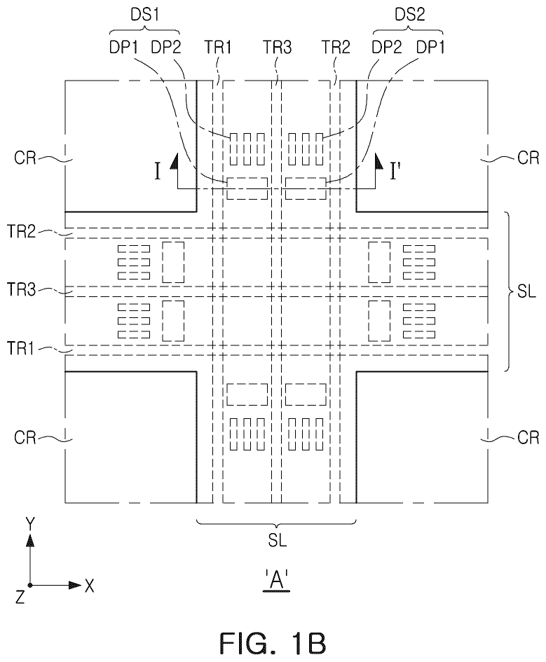

FIG. 1A is a perspective view of a wafer structure 100 according to an example embodiment, and FIG. 1B is a partial enlarged view of an area ‘A’ of FIG. 1A.

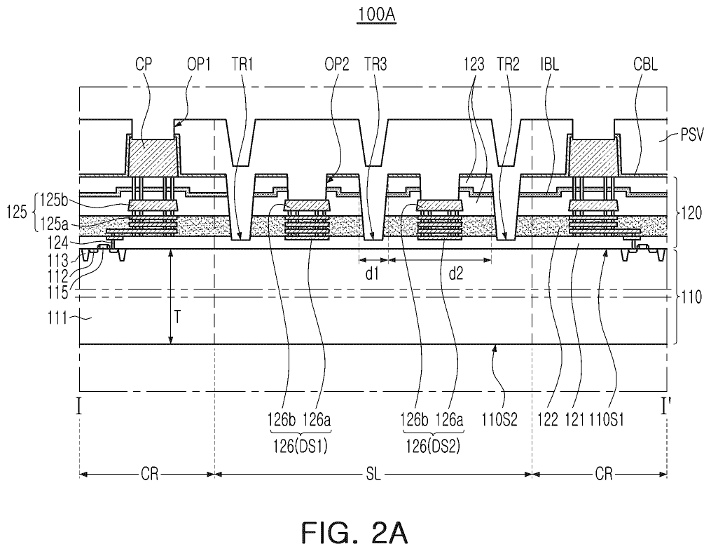

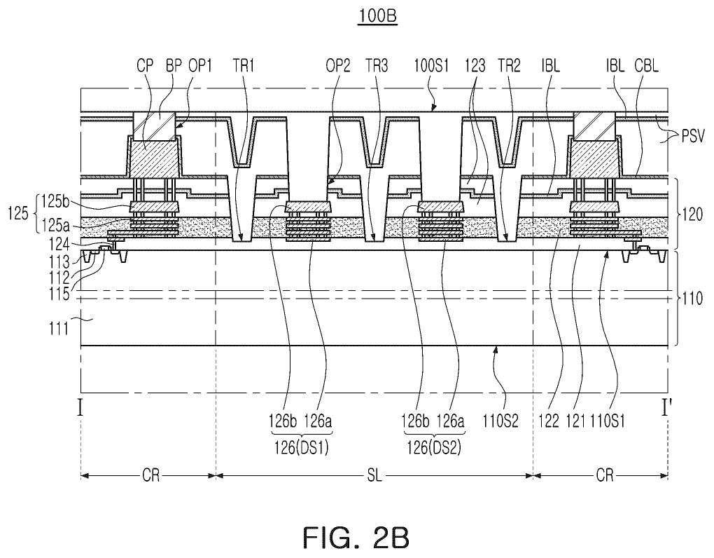

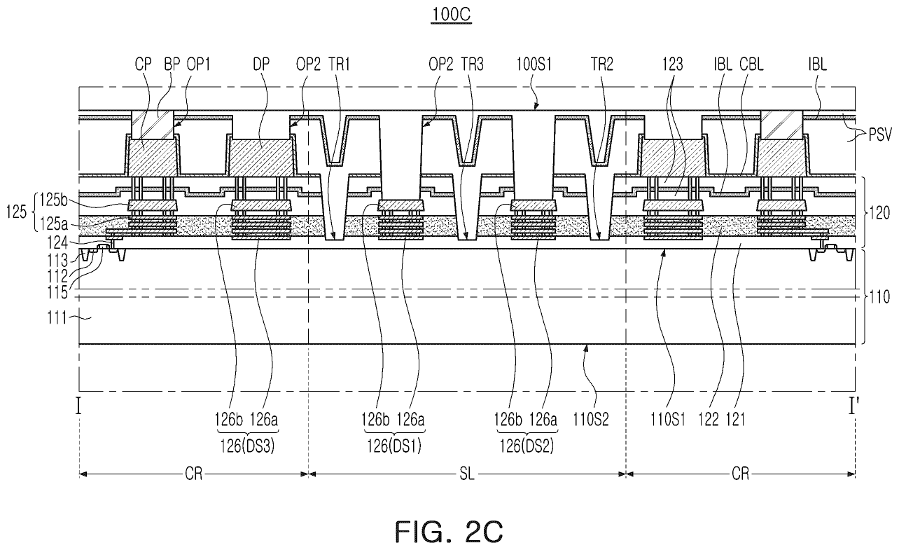

Referring to FIGS. 1A and 1B, a semiconductor wafer structure 100, also referred to as a “wafer structure,” may include a semiconductor substrate 110 and a device layer 120. The semiconductor substrate 110 may be a semiconductor wafer made of a silicon semiconductor or a compound semiconductor. The semiconductor substrate 110 may be a wafer having a disc shape whose thickness is thin through a back-grinding process. Alternatively, the semiconductor substrate 110 may be a wafer to which the back-grinding process is not applied and may be relatively thick. The device layer 120 may be formed on one surface of the semiconductor substrate 110 on which individual devices are formed, for example, on an active surface. The device layer 120 may include a dielectric material layer and conductive structures. The detailed structure of the semiconductor substrate 110 and the device layer 120 will be described later with reference to FIGS. 2A to 2C. According to an example embodiment, the wafer structure 100 may have a notch NC formed in one area of the edge and used as a reference point for wafer alignment.

The wafer structure 100 may include chip regions CR and a scribe region SL. Hereinafter, the chip regions CR and the scribe region SL may be referred to as two different regions of the wafer structure 100. The chip regions CR may be regions in which memory devices and/or logic devices are formed. The chip regions CR may be surrounded by the scribe region SL and may be disposed spaced apart from each other in the first horizontal direction (X-direction) and the second horizontal direction (Y-direction). The chip regions CR may be separated by a sawing process to form individual chips. The sawing processes may include blade sawing, laser sawing, stealth laser sawing, and plasma sawing. Because some sawing process such as blade sawing process may cause stress on the wafer and damage to the edge of the chip regions CR, scribing lanes included in the scribe regions SL for the sawing process need to be spaced apart from the edge of the chip region. Especially, for thinner wafers, the distance between the chip regions CR and the scribing lanes have to be longer for preventing cracks on the edge of the chip during the sawing process. The scribe region SL may be set to have enough width to avoid such problems during the sawing process. The wider width of the scribe region SL, of course, reduce the number of individual chips formed on the wafer structure 100. Furthermore, residual portion of the scribe region SL may remain along the side of the chip regions CR which is a redundant portion of the individual chip. More advanced sawing processes such as the laser sawing and the plasma sawing may be applied to the wafer structure 100 with minimal stress and damage on the wafer, and the distance between the chip regions and the scribing lane may be shorter. This advanced sawing process may be applied to the wafer structure 100 whose thickness is thin. As the width of the scribe region SL of the wafer structure 100 is determined by targeting a specific sawing process, other sawing process may not be used for the wafer structure 100. According to an embodiment, the scribe regions SL may include multiple scribing lanes in which scribing operation is performed. By selecting different scribing lanes, various sawing process may be applied. The scribing lanes may be a metal-free trench structure formed within the scribe lane SL, with which easy and clear cutting may be possible during the sawing process. The chip regions CR may be arranged in multiple rows and multiple columns with the scribe region SL therebetween. The scribe region SL may be a region for cutting or dicing the wafter structure 100 to separate the chip regions CR. The scribe region SL may extend in a first horizontal direction (X-direction) and a second horizontal direction (Y-direction). The scribe regions SL may include a portion extending in the first horizontal direction (X-direction) and a portion extending in the second horizontal direction (Y-direction), and the portions may intersect at corner areas of the chip regions CR.

The wafer structure 100 may further include dummy structures DS1 and DS2 within the scribe region SL. The dummy structures DS1 and DS2 may include conductive patterns formed within the device layer 120. For example, the dummy structures DS1 and DS2 may include a test pattern DP1 such as a Test Element Group (TEG) pattern and an Electrical Die Sorting (EDS) pattern, and an alignment key pattern DP2 for aligning a mask. The plurality of trenches TR1, TR2 and TR3 may penetrate at least a portion of the device layer 120 in a vertical direction (Z-direction). The plurality of trenches TR1, TR2 and TR3 may extend in the first and second horizontal directions along the scribe region SL, and each of the plurality of trenches TR1, TR2 and TR3 may intersect at corner areas of chip regions CR. The plurality of trenches TR1, TR2 and TR3 extending along a scribe region SL in a first horizontal direction (X-direction) may be spaced apart from each other in a second horizontal direction (Y-direction), and a plurality of trenches TR1, TR2 and TR3 extending along a scribe region SL in a second horizontal direction (Y-direction) may be spaced apart from each other in the first horizontal direction (X-direction).

The plurality of trenches TR1, TR2 and TR3 may include a pair of trenches TR1 and TR2 disposed at a first side and a second side of the scribe region SL respectively and a central trench TR3 disposed at center of the scribe region SL and between the pair of trenches TR1 and TR2. The first side is one edge side of the scribe regions SL and the second side is the other edge side of the scribe regions SL. The pair of trenches TR1 and TR2 may also be referred to as a “first trench” and a “second trench” respectively, and the central trench TR3 may also be referred to as a “third trench. ” The first trench is disposed at the first side and the second trench is disposed at the second side. The third trench is disposed between the first trench and the second trench. The wafer structure 100 may further include dummy structures DS1 and DS2. The pair of trenches TR1, and TR2 may be disposed at the sides of the dummy structures DS1 and DS2 and the central trench TR3 may be disposed between the dummy structures DS1 and DS2. According to an example embodiment, the plurality of trenches TR1, TR2 and TR3 may be a metal free area within the scribe region SL to which various types of sawing processes may be applied. For example, for clear removing of the dummy structures DS1 and DS2 from the wafer structure 100 during the sawing process, the sawing process may be performed on the pair of trenches TR1 and TR2 disposed at the first and second sides of the scribe region SL. However, the sawing process on the pair of trenches TR1 and TR2 may bring undesired damage on the chip regions. Especially, the chip regions CR formed in the thinned wafer may be damaged from the sawing process performed on the first and second trenches TR1 and TR2. To avoid damage to the chip regions CR in the thinned wafer structure 100 having a thickness of about 30 μm or less, the sawing process may be performed on a central trench TR3 more spaced apart from the chip regions CR.

FIGS. 2A to 2C are partial enlarged views of wafer structures 100A, 100B and 100C according to example embodiments respectively. FIGS. 2A to 2C illustrate cross-sectional views taken along line I-I′ of FIG. 1B respectively.

Referring to FIG. 2A, a wafer structure 100A may include a semiconductor substrate 110 having a first surface 110S1 and an opposite second surface 110S2, and a device layer 120 on the first surface 110S1 of the semiconductor substrate 110. According to an example embodiment, the wafer structure 100A may further include a passivation layer PSV covering the device layer 120.

The semiconductor substrate 110 may be composed of a body 111 including a semiconductor material. For example, the body 111 may be a semiconductor wafer made of semiconductor material such as silicon, germanium, or a compound semiconductor such as silicon carbide (SiC), gallium arsenide (GaAs), indium arsenide (InAs), and indium phosphide (InP). The body 111 may include a conductive region 112 and an isolation region 113. The conductive region 112 may be, for example, a well doped with an impurity, or an active region doped with impurities. The isolation region 113 is a device isolation structure having a shallow trench isolation (STI) structure which may be formed with silicon oxide. The thickness T of the semiconductor substrate 110 may be thinned through a back-grinding process. For example, the wafer structure 100A may be thinned to the thickness T of about 30 μm or less after the back-grinding process.

Individual devices 115 may be formed on the first surface 110S1of the semiconductor substrate 110. The individual devices 115 may be connected to the connection structure 125 of the device layer 120 by an interconnection portion 124 such as contact plug. The individual devices 115 may include a memory cell array including switching devices and data storage devices, and logic devices including MOSFETs, capacitors, and resistors. For example, the individual devices 115 may include various active devices and/or passive devices such as system LSI, CMOS image sensor (CIS) and micro-electro-mechanical system (MEMS), FETs such as planar FETs or FinFETs, memory devices such as flash memory, DRAM, SRAM, electrically erasable programmable ROM (EEPROM), phase-change RAM (PRAM), magnetoresistive RAM (MRAM), ferroelectric RAM (FeRAM) and resistive RAM (RRAM), and logic devices such as AND, OR, and NOT.

The device layer 120 may include a lower insulating layer 121, an interlayer insulating layer 122, an upper insulating layer 123, connection structures 125, and dummy structures 126. The lower insulating layer 121, the interlayer insulating layer 122, and the upper insulating layer 123 may be sequentially stacked on the first surface 110S1of the semiconductor substrate 110. The lower insulating layer 121, the interlayer insulating layer 122, and the upper insulating layer 123 may partially surround the connection structures 125 and the dummy structures 126 respectively.

The lower insulating layer 121 may cover the semiconductor substrate 110 and individual devices 115. The lower insulating layer 121 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, and Tetra Ethyl Ortho Silicate (TEOS), or combinations thereof.

The interlayer insulating layer 122 may include a material having a lower permittivity or a lower dielectric constant than the lower insulating layer 121 and the upper insulating layer 123. The interlayer insulating layer 122 may be composed of fluorine doped silicon oxide (SiOF), carbon doped silicon oxide (SiOC), a spin-on silicone based polymer, or a porous layer. The spin-on silicone based polymer may be hydrogen silsesquioxane (HSQ), methylsilsesqioxane (MSQ), poly-tetrafluoroethylene (PTFE) layer, fluorinated poly-aryl-ether (FLARE), poly-paraxylylene, benzo cyclobutene (BCB), or silicon low K polymer (SILK). The interlayer insulating layer 122 may also include various materials having lower dielectric constants than the lower insulating layer 121 and the upper insulating layer 123. The interlayer insulating layer 122 may be composed of silicon oxyhydrocarbide (SiOCH), silicon carbonitride (SiCN), or combinations thereof. The interlayer insulating layer 122 may be composed of a plurality of low-k dielectric layers sequentially stacked on the lower insulating layer 121.

The upper insulating layer 123 surrounds the upper portions of the connection structures 125 and the dummy structures 126, and may cover uppermost patterns of the connection structures 125 and the dummy structures 126. The upper insulating layer 123 may include silicon oxide, silicon nitride, silicon oxynitride, or combinations thereof. The upper insulating layer 123 may include Tetra Ethyl Ortho Silicate (TEOS). An insulating barrier film IBL may be disposed within the upper insulating layer 123. The insulating barrier film IBL may include a material having an etching selectivity with respect to some portion of the upper insulating layer 123, specifically, the portion of the upper insulating layer 123 located below the insulating barrier film IBL. The insulating barrier film IBL may include silicon nitride, silicon carbide, silicon oxynitride, or silicon carbonitride. According to an example embodiment, the upper insulating layer 123 may include openings OP2 exposing dummy structures 126 such as TEG patterns. The openings OP2 of the upper insulating layer 123 may be covered by a passivation layer PSV after completing the test on the TEG patterns.

The connection structures 125 may have a multilayer structure in which conductive patterns and conductive vias are alternately disposed in a vertical direction within the chip regions CR. The connection structures 125 may be formed of a conductive material including at least one of aluminum (Al), copper (Cu), nickel (Ni), tungsten (W), platinum (Pt), and gold (Au). The connection structures 125 may be electrically connected to the conductive region 112 and/or at least one individual device 115. The connection structures 125 may include a lower structure 125a in the interlayer insulating layer 122 and an upper structure 125a in the upper insulating layer 123. The number of layers forming the lower structure 125a and the upper structure 125b may not be limited to the number of layers illustrated in the drawing. The upper structure 125b of the connection structures 125 may be connected to front pads CP for communicating data signals through the front pads CP. The front pads CP may be disposed above or on the connection structures 125.

The dummy structures 126 may have a multilayer structure in which conductive patterns and conductive vias corresponding to the connection structures 125 are alternately disposed within the scribe region SL. The dummy structures 126 may be composed of a conductive material similar to the connection structures 125. The dummy structures 126 may form a TEG pattern, an EDS pattern, and an alignment key pattern. The dummy structures 126 may include a lower structure 126a within the interlayer insulating layer 122 and an upper structure 126a within the upper insulating layer 123. The number of layers forming the lower structure 126a and the upper structure 126b may not be limited to the number of layers illustrated in the drawing. The upper structure 126b of the dummy structures 126 may provide test pads, also referred to as “dummy pads DP,” for testing individual devices 115 and connection structures 125. The upper structure 126b of the dummy structures 126 may be formed with a different number of layers from the upper structure 125b of the connection structures 125, thereby the uppermost pattern of the upper structure 126b of the dummy structures 126 may be located at a lower level than the uppermost pattern of the upper structure 125b of the connection structures 125.

The plurality of trenches TR1, TR2 and TR3 may penetrate at least a portion of the device layer 120. For example, The plurality of trenches TR1, TR2 and TR3 may penetrate the upper insulating layer 123 and the interlayer insulating layer 122. The plurality of trenches TR1, TR2 and TR3 may extend vertically at least to the upper surface of the lower insulating layer 121. The plurality of trenches TR1, TR2 and TR3 may extend further into the interior of the lower insulating layer 121.

According to an example embodiment, the plurality of trenches TR1, TR2 and TR3 within the scribe region SL may be used as cutting lanes or scribing lanes applicable to various sawing processes, thereby allowing a plurality of different dicing methods for cutting the wafer structure 100A to be applicable. Because such different dicing methods may be applied regardless of the thickness of the wafter structures 100, productivity may be improved. The plurality of trenches TR1, TR2 and TR3 are within the scribe region SL and may include a first trench TR1 extending along a first side of the scribe region SL, a second trench TR2 extending along a second side of the scribe region SL, and a third trench TR3 disposed between the first trench TR1 and the second trench TR2. The first side is one edge side of the scribe regions SL and the second side is the other edge side of the scribe regions SL. The first trench is disposed at the first side, and the second trench is disposed at the second side. The third trench is disposed between the first trench and the second trench and extends along the center of scribe region SL. The first trench TR1 and the second trench TR2 may be disposed adjacent to the boundary of the chip region CR and the scribe region SL, and extend along the first and second sides of the scribe region SL.

The dummy structures 126 may be disposed between the first trench TR1 and the third trench TR3 and between the second trench TR2 and the third trench TR3. The dummy structures 126 may include a first group of dummy structures DS1 disposed between the first trench TR1 and the third trench TR3 and a second group of dummy structures DS2 disposed between the second trench TR2 and the third trench TR3.

The width d1 of each of the plurality of trenches TR1, TR2 and TR3 may be about 10 μm or more. Alternatively, the width d1 may be in a range of 10 μm to 50 μm, 10 μm to 40 μm, 10 μm to 30 μm, or 10 μm to 20 μm. If the width d1 of each of the plurality of trenches TR1, TR2 and TR3 is less than about 10 μm, the interlayer insulating layer 122 may be exposed to the cut surface after the sawing process, which may cause interface delamination.

The spacing distance d2 between the plurality of adjacent trenches TR1, TR2 and TR3 may be about 50 μm or more. Alternatively, the spacing distance d2 may be in a range of 50 μm to 100 μm, 50 μm to 80 μm, or 50 μm to 60 μm. When the spacing distance d2 between the plurality of trenches TR1, TR2 and TR3 is less than about 50 μm, the dummy structures 126 may be exposed to the cut surface after the sawing process or burrs may be generated.

The passivation layer PSV is formed on the device layer 120 and may include first openings OP1 that expose at least a portion of the front pads CP. Referring to FIG. 2B, the passivation layer PSV may also include second openings OP2 exposing the test dummy structure 126. The passivation layer PSV may be composed of a single-layer or multi-layer insulating film including an oxide and/or a nitride. A capping barrier film CBL extending along the upper insulating layer 123 may be formed between the passivation layer PSV and the front pads CP. The capping barrier film CBL may include at least one of silicon nitride (SiN), silicon carbide (SiC), silicon oxynitride (SiON), silicon carbonitride (SiCN), aluminum nitride (AlN), aluminum oxynitride (AlON), aluminum oxide (AlO), and aluminum oxycarbide (AlOC). The passivation layer PSV may fill at least a portion of the plurality of respective trenches TR1, TR2 and TR3.

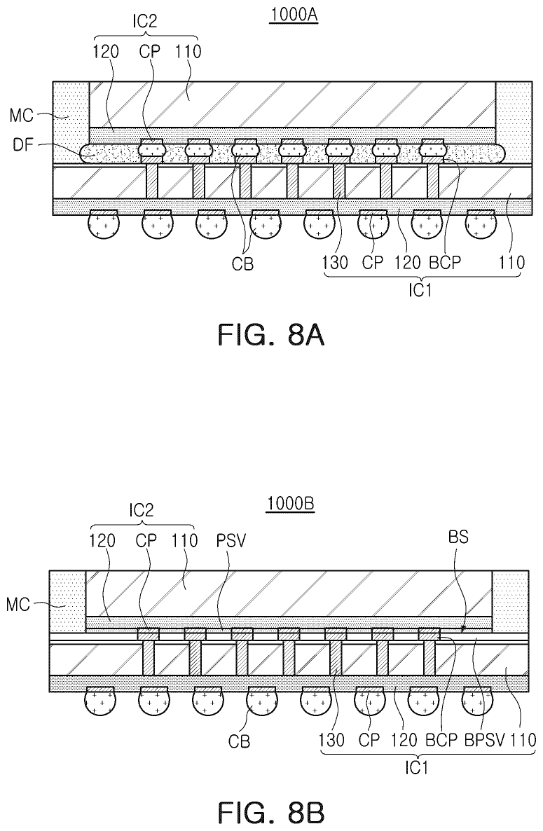

Referring to FIG. 2B, a wafer structure 100B may further include bonding pads BP. The bonding pads BP may be formed on the front side pads CP by plugging a contact hole through the passivation layer PSV and be connected to the front side pads CP. The passivation layer PSV may also include second openings OP2 exposing the test dummy structure 126. The top surface of the bonding pads BP and the top surface of the passivation layer PSV may be leveled flat for direct bonding or hybrid bonding as shown in FIG. 8B. The upper surfaces of the bonding pads BP and the upper surface of the passivation layer PSV may be planarized to form flat front surface 100S1 of the wafer structure 100B. The bonding pads BP may include a material that forms an intermetallic bond. For example, the bonding pads BP may include one of copper (Cu), nickel (Ni), gold (Au), and silver (Ag), or alloys thereof. The passivation layer PSV may include a material capable of forming an inter-dielectric bond. For example, the passivation layer PSV may include silicon oxide (SiO) or silicon carbonitride (SiCN).

Referring to FIG. 2C, a wafer structure 100C of an example embodiment may include a third group of dummy structures DS3. The dummy structures 126 may further include a third group of dummy structures DS3 disposed within the chip regions CR. The third group of dummy structures DS3 may include an EDS pattern. The upper structure 126b of the third group of dummy structures DS3 may provide a dummy pad DP for electrical inspection. The second opening OP2 and the dummy pad DP may be covered by a passivation layer PSV after the electrical inspection is completed.

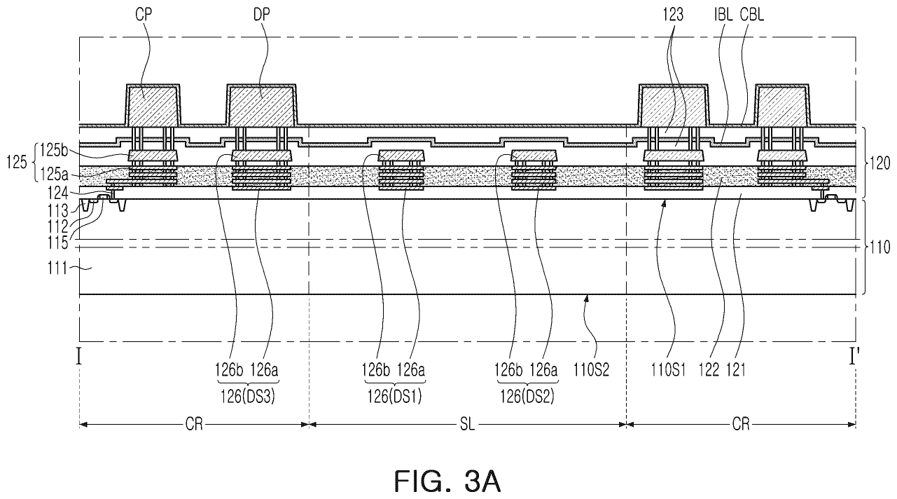

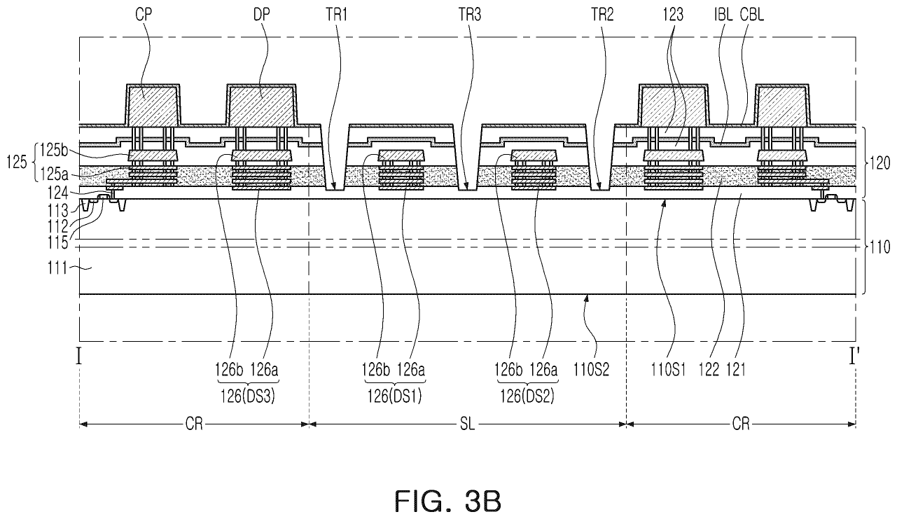

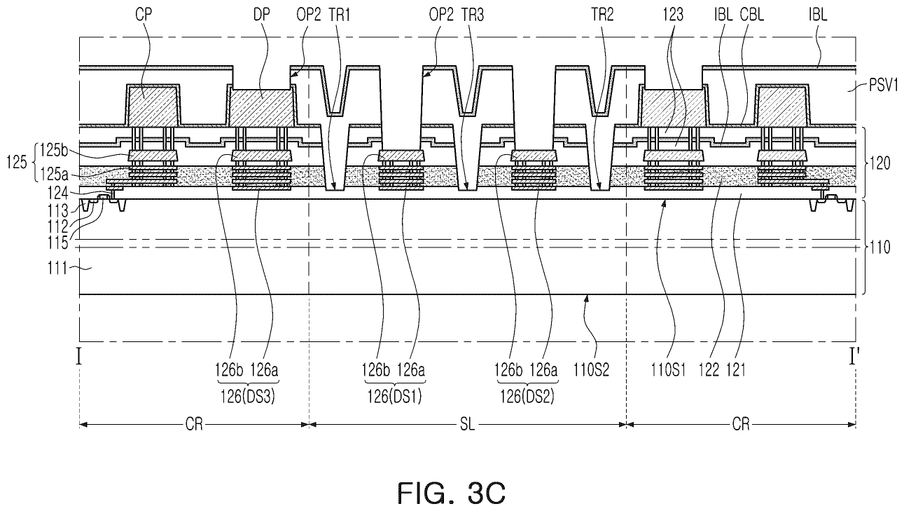

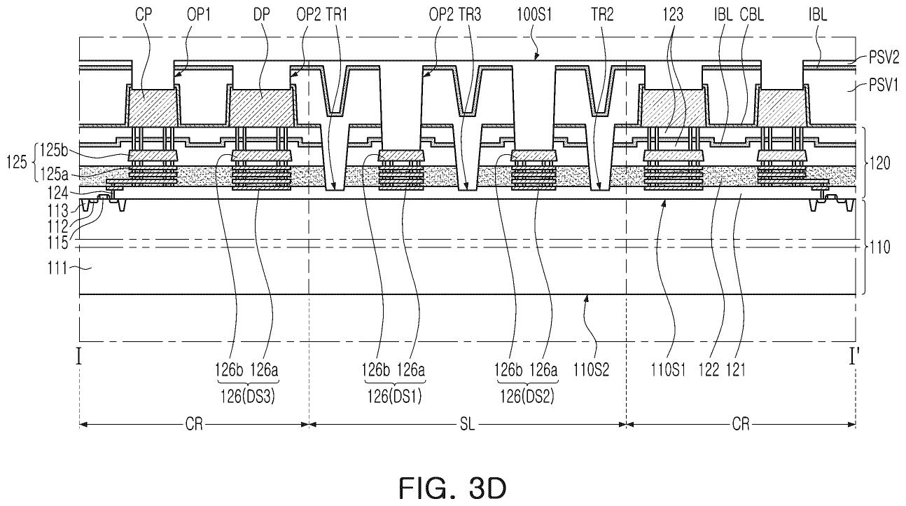

FIGS. 3A to 3D are partial enlarged views illustrating a process of manufacturing the wafer structure 100C of FIG. 2C.

Referring to FIG. 3A, a capping barrier film CBL may be formed on the device layer 120. The capping barrier film (CBL) may be formed using a deposition technique having excellent step coating properties. For example, the capping barrier film CBL may be formed by Chemical Vapor Deposition (CVD) or Plasma-enhanced CVD (PECVD).

Referring to FIG. 3B, trenches TR1, TR2 and TR3 may be formed in the scribe region SL. The trenches TR1, TR2 and TR3 may be formed by performing a dry etching process or a wet etching process. The trenches TR1, TR2 and TR3 may be formed to penetrate the interlayer insulating layer 122 of the device layer 120. The trenches TR1, TR2 and TR3 may be formed in an area where the dummy structures 126 are not present. The inner walls of the trenches TR1, TR2 and TR3 may be formed in a straight or curved shape, or in a shape having a wave pattern depending on the etching process. The etching process may include Bosch process.

Referring to FIG. 3C, a lower passivation layer PSV1 filling the trenches TR1, TR2 and TR3 may be formed. The lower passivation layer PSV1 may be formed by a deposition process such as CVD or PECVD. The lower passivation layer PSV1 may cover a portion of the interlayer insulating layer 122 exposed to the inner walls of the trenches TR1, TR2 and TR3. After forming an insulating barrier film IBL on the lower passivation layer PSV, openings OP2 may be formed to open the dummy pads DP.

Referring to FIG. 3D, the upper passivation layer PSV2 may be formed. The upper passivation layer PSV2 may be formed to cover the openings OP2 and the dummy pads DP. Thereafter, openings OP1 may be formed to open the front pads CP, and filled with a conductive material to form a bonding pad as shown in FIG. 2C.

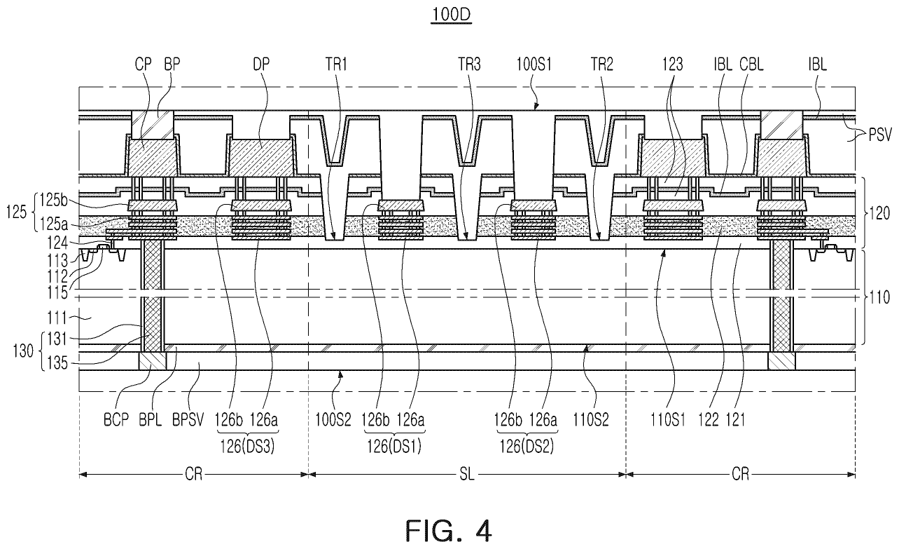

FIG. 4 is a partial enlarged view of a wafer structure 100C according to an example embodiment.

Referring to FIG. 4, the wafer structure 100D, an example embodiment further includes back pads BCP and through-electrodes 130.

The back pads BCP may be disposed on the second surface 110S2 of the semiconductor substrate 110. The back pads BCP may be composed of a conductive material including at least one of aluminum (Al), copper (Cu), nickel (Ni), tungsten (W), platinum (Pt), and gold (Au). The back pads BCP may be electrically insulated from the semiconductor substrate 110 by an insulating protective layer (BPL). The insulating protective layer BPL may include silicon oxide, silicon nitride, silicon carbide, silicon oxynitride, or silicon carbonitride. The back pads BCP may be electrically connected to the connection structures 125 or the front pads CP through the through-electrodes 130.

The through-electrodes 130 may extend from the first surface 110S1of the semiconductor substrate 110 to the second surface 110S2. The through-electrodes 130 may electrically connect the front pads CP and the back pads BCP. The through-electrodes 130 may include a via plug 135 and a side insulating film 131 surrounding a side surface of the via plug 135. The side insulating film 131 may electrically isolate the via plug 135 from the semiconductor substrate 110. The via plug 135 may include tungsten (W), titanium (Ti), aluminum (Al), or copper (Cu), and may be formed by a plating process, a PVD process, or a CVD process. The side insulating film 131 may include a metal compound such as tungsten nitride (WN), titanium nitride (TiN), or tantalum nitride (TaN), and may be formed by a PVD process or a CVD process.

The back pads BCP may be provided for direct bonding or hybrid bonding. The back pads BCP may be coplanar with the back passivation layer BPSV to form a flat back surface 100S2 of the wafer structure 100C. The back passivation layer BPSV may include a material capable of forming a dielectric bond in which the material may include silicon oxide (SiO) or silicon carbon nitride (SiCN).

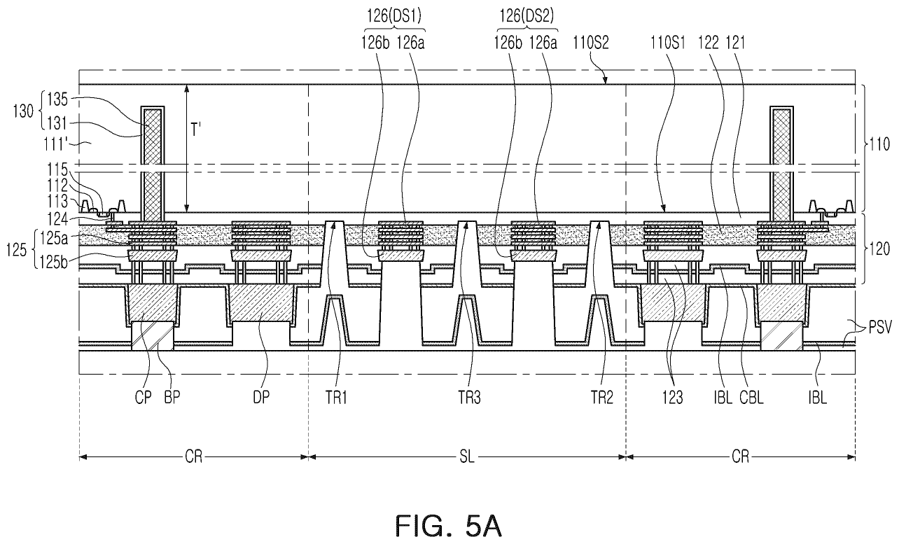

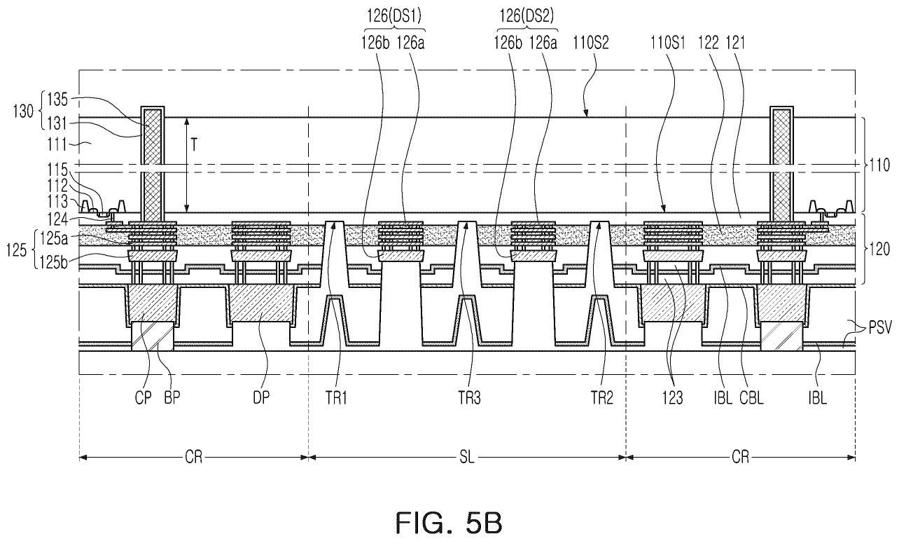

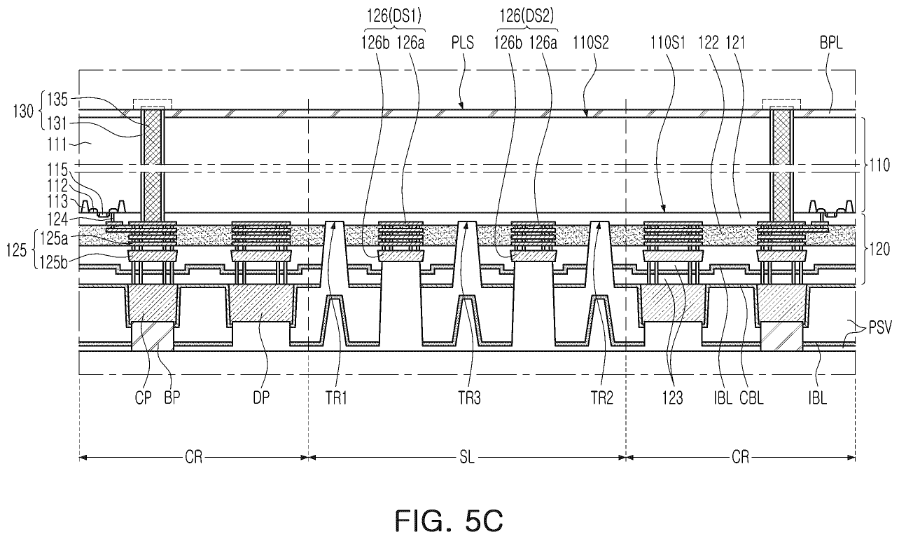

FIGS. 5A to 5C are partial enlarged views illustrating a manufacturing process of the wafer structure 100C of FIG. 4.

Referring to FIG. 5A, for exposing the through-electrodes 130 of the semiconductor substrate 110, the back grinding process may be processed to the semiconductor substrate 110 and may remove a back-side portion of the semiconductor substrate 111′. The back-side portion of the semiconductor substrate 111′ may have a thickness (T′) so that the through-electrodes 130 may not completely pass through the back-side portion of the semiconductor substrate 111′. Before the back grinding process, the second surface 110S2 of the semiconductor substrate 110 on which the back grinding process is performed may be positioned over the tops of the through-electrodes 130 because the through-electrodes 130 are formed not to pass completely through the back-side portion of the semiconductor substrate 111′.

Referring to FIG. 5B, the semiconductor substrate 110 may be polished during the back grinding process to expose the through-electrodes 130. The thickness of the body 111 of the semiconductor substrate 110 may be reduced to a thickness T through the polishing process. By removing the back-side portion of the semiconductor substrate 111′, the second surface 110S2 of the semiconductor substrate 110 may be positioned lower than the tops of the through-electrodes 130. The polishing process may use a chemical-mechanical polishing (CMP) process, an etch-back process, or a combination thereof. The thickness of the body 111 may be reduced to a thickness that the through-electrodes 130 may be sufficiently exposed.

Referring to FIG. 5C, an insulating protective layer BPL may be formed on the second surface 110S2 of the semiconductor substrate 110. The insulating protective layer BPL may be formed by a deposition process such as CVD. The insulating protective layer BPL may be formed with a buffer film including silicon nitride or silicon oxynitride. By applying a planarization process to the insulating protective layer BPL covering the tops of the through-electrodes 130, a planarization surface PLS may be formed in which the insulating protective layer BPL and the through-electrodes 130 have been partially removed. Thereafter, back pads BCP may be formed on the planarization surface PLS.

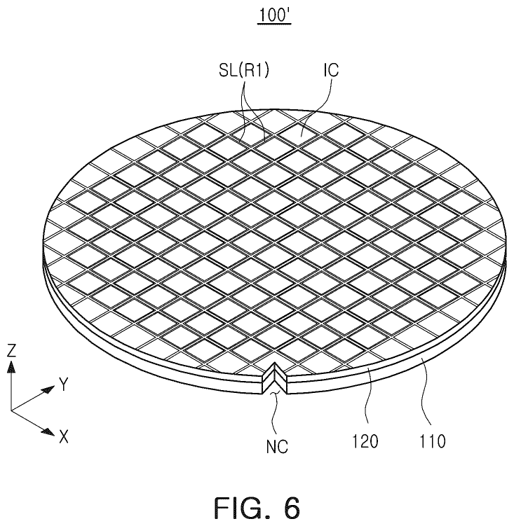

FIG. 6 is a perspective view of an example embodiment of a wafer structure 100′ to which a sawing process is applied.

Referring to FIG. 6, the wafer structure 100′ to which the sawing process is applied may include individual chips IC separated along a cut portion R1 of a scribe region SL. The individual chips IC may include chip regions CR described with reference to FIG. 1A. The scribe region SL may include a cut portion R1 to be removed through sawing process and a residual portion R2 around the cut portion R1. The cut portion R1 of the wafer structures 100′ according to an example embodiment may be differently determined depending on the thickness of the wafer structure, the type of subsequent process, and the sawing method.

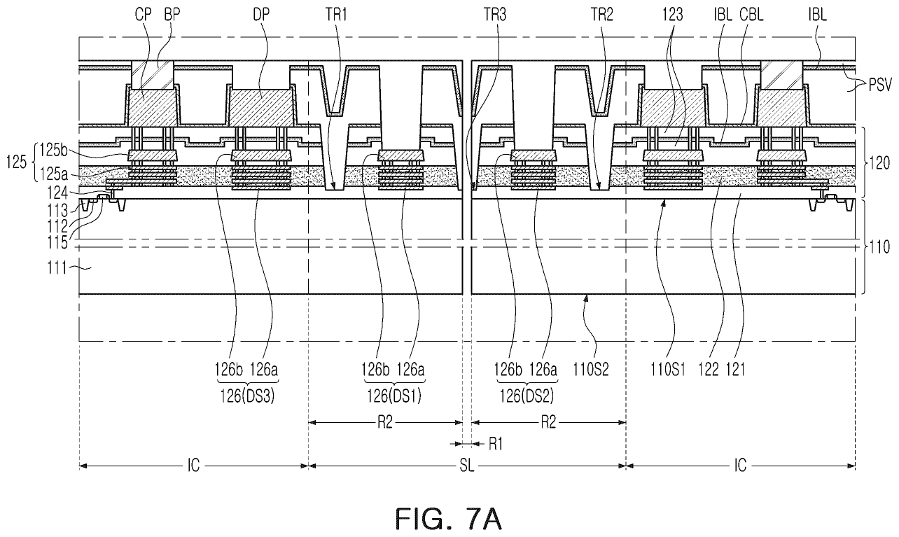

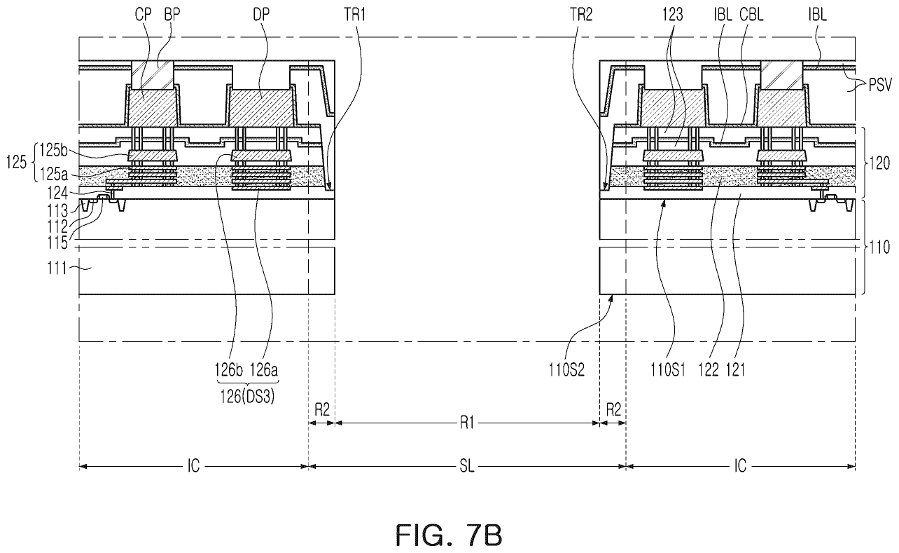

FIGS. 7A and 7B are partial enlarged views of the wafer structures 100′ of an example embodiment to which the sawing process is applied.

Referring to FIG. 7A, the wafer structure 100′ may be sawed on the central trench TR3. The central trench TR3 is a metal-free area that secures maximum margin from individual chips IC, and various sawing processes such as blade sawing, laser sawing, stealth laser sawing, and plasma sawing may be applied alone or in combination. Although various sawing process may be applied without restriction, residual portion of the individual chips IC after the sawing process may bring an undesired effect on back-end process such as packing process.

Referring to FIG. 7B, the wafer structure 100′ may be sawed based on a pair of trenches TR1 and TR2 respectively. The pair of trenches TR1 and TR2 are disposed within the scribe region SL and extend along the first and second sides of the scribe region SL. The pair of trenches TR1 and TR2 may be characterized as metal-free areas and no dummy structure 126 may be formed in the residual portion R2 described above. More advanced sawing processes such as laser sawing, stealth laser sawing, and plasma sawing may be selected for sawing process on the pair of trenches TR1 and TR2. Because either the pair of trenches TR1 and TR2 or the central trench TR3 may be selected for the different thickness of the wafer structure 100, various sawing process without restriction may be applied.

FIGS. 8A and 8B are cross-sectional views of semiconductor packages including individual chips separated from wafer structures of example embodiments.

The individual chips IC1 and IC2 may be separated from the wafer structure 100.

Referring to FIG. 8A, a semiconductor package 1000A of an example embodiment may include individual chips IC1 and IC2 that are stacked vertically. At least some of the individual chips IC1 and IC2 may include through electrodes 130 and back pads BCP that electrically connect the individual chips IC1 and IC2 to each other. Though two individual chips IC1 and IC2 are illustrated in the drawing, the number of individual chips are not limited to the number shown in the drawing and may be greater than two. According to an example embodiment, the semiconductor package 1000A may further include a molding member (MC) that covers at least some of the individual chips IC1 and IC2.

The individual chips IC1 and IC2 may be bonded to each other by a thermocompression bonding process. Alternatively, the individual chips IC1 and IC2 may be connected to each other through connection bumps CB and an adhesive film layer DF. The connection bumps CB may be disposed on the front side pads CP and back pads BCP of the first chip IC1. The connection bumps BP may have a combined form of a pillar and a ball. The pillar may include copper (Cu) or an alloy of copper (Cu), and the ball may include a low-melting point metal such as tin (Sn) or an alloy (Sn—Ag—Cu) including tin (Sn). The adhesive film layer DF may be formed using an adhesive film or an adhesive paste. The adhesive film DF may be a non-conductive film (NCF), but is not limited thereto.

Referring to FIG. 8B, a semiconductor package 1000B may include individual chips IC1 and IC2 that are directly bonded and coupled without a separate connecting member such as a solder bump or a copper post. The semiconductor package 1000B may include a bonding surface BS in which the upper surface of the first chip IC1 and the lower surface of the second chip IC2 are bonded. The bonding surface BS may be formed by metal bonding and dielectric bonding. For example, the back passivation layer BPSV of the first chip IC1 and the passivation layer PSV of the second chip IC2 forming the bonding surface BS may be bonded and combined with each other.

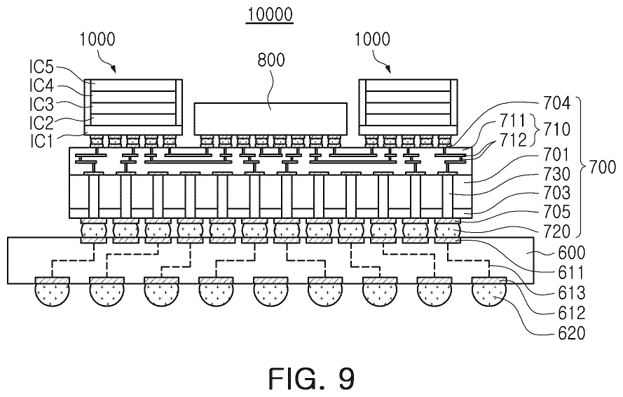

FIG. 9 is a cross-sectional side view of a semiconductor package 10000 including individual chips separated from wafer structures of an example embodiment.

Referring to FIG. 9, the semiconductor package 10000 of an example embodiment may include a package substrate 600, an interposer substrate 700, a processor chip 800, and a memory structure 1000.

The memory structure 1000 may be understood as a package structure in which individual chips IC1, IC2, IC3, IC4 and IC5 are stacked in the manner described with reference to FIG. 8A or FIG. 8B.

The package substrate 600 is a support substrate on which the interposer substrate 700 is mounted, and may be a semiconductor package substrate including a printed circuit board (PCB), a ceramic substrate, a glass substrate, or a tape connection substrate. If the package substrate 600 is a printed circuit board, the package substrate 600 may be in the form of a body copper-clad laminate or in the form in which a connection layer is additionally stacked on one side or both sides of the copper-clad laminate.

The interposer substrate 700 may include a substrate 701, a lower protective layer 703, a lower pad 705, an interconnection structure 710, a metal bump 720, and a through-via 730. The memory structure 1000 and the processor chip 800 may be electrically connected to each other via the interposer substrate 700. The interposer substrate 700 may connect the metal bumps 720 to the package substrate 600.

The substrate 701 may be formed of, for example, any one of a silicon, organic, plastic, and glass substrate. When the substrate 701 is a silicon substrate, the interposer substrate 700 may be referred to as a silicon interposer, and a lower protective layer 703 may be disposed on the lower surface of the substrate 701, and a lower pad 705 may be disposed on the lower protective layer 703. The lower pad 705 may be connected to a through via 730.

The interconnection structure 710 may be disposed on the upper surface of the substrate 701 and may include an interlayer insulating layer 711 and a single-layer or multi-layer connection structure 712. When the interconnection structure 710 is formed of a multi-layer connection structure, connection patterns of different layers may be connected to each other through contact vias.

The through via 730 may electrically connect the lower pad 705 and the upper pad 704 by penetrating the substrate 701. In some embodiments, the through via 730 may extend into the interior of the interconnect structure 710 and be electrically connected to the connection of the interconnect structure 710. When the substrate 701 is silicon, the through via 730 may be referred to as a through-silicon via (TSV).

The interposer substrate 700 may be used for the purpose of converting or transmitting an input electrical signal between the memory structure 1000 or the processor chip 800. The interposer substrate 700 may not include components such as active components or passive components.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), and the like.

As set forth above, according to example embodiments, by forming a plurality of trenches within a scribe region, a semiconductor wafer structure compatible with various types of sawing processes may be provided.

While example embodiments have been illustrated and described above, it will be apparent to those skilled in the art that modifications and variations could be made without departing from the scope of the present inventive concept as defined by the appended claims.

What is claimed is:

1. A wafer structure comprising:
a semiconductor substrate having a first surface on which individual devices are formed and a second surface opposite to the first surface, and including chip regions and a scribe region for separating each of chip regions;
an interlayer insulating layer on the first surface of the semiconductor substrate;
an upper insulating layer on the interlayer insulating layer;
connection structures formed within the chip regions and at least partially surrounded by the interlayer insulating layer and the upper insulating layer respectively;
a first trench formed within the scribe region, and extending along a first side of the scribe region and penetrating the upper insulating layer and the interlayer insulating layer;
a second trench formed within the scribe region, and extending along a second side of the scribe region and penetrating the upper insulating layer and the interlayer insulating layer;
a third trench formed within the scribe region, and extending along between the first trench and the second trench and penetrating the upper insulating layer and the interlayer insulating layer; and
dummy structures disposed between the first trench and the third trench and between the second trench and the third trench, and at least partially surrounded by the interlayer insulating layer and the upper insulating layer respectively.

2. The wafer structure of claim 1, wherein the first trench, the second trench, and the third trench are spaced apart from each other in a first horizontal direction and each of the first to third trenches extends in a second horizontal direction perpendicular to the first horizontal direction.

3. The wafer structure of claim 1, further comprising a lower insulating layer disposed between the semiconductor substrate and the interlayer insulating layer and covering the individual devices,
wherein each of the first trench, the second trench, and the third trench penetrates the interlayer insulating layer and the upper insulating layer and extends in a vertical direction at least to an upper surface of the lower insulating layer.

4. The wafer structure of claim 1, wherein a separation distance between the first trench and the third trench and a separation distance between the second trench and the third trench are about 50 μm respectively.

5. The wafer structure of claim 1, wherein a width of each of the first trench, the second trench, and the third trench is about 10 μm.

6. The wafer structure of claim 1, wherein the dummy structures include at least one of a test pattern and an alignment key pattern.

7. The wafer structure of claim 1, wherein the dummy structures include a first group of dummy structures between the first trench and the third trench, and a second group of dummy structures between the second trench and the third trench.

8. The wafer structure of claim 7, wherein the dummy structures further include a third group of dummy structures within the chip regions.

9. The wafer structure of claim 1, further comprising:
front pads above the connection structures;
dummy pads above the dummy structures; and
a passivation layer covering the front pads and the dummy pads, and filling the first trench, the second trench and the third trench.

10. The wafer structure of claim 9, wherein the passivation layer includes a plurality of openings exposing the front pads.

11. The wafer structure of claim 10, further comprising bonding pads plugging the plurality of openings of the passivation layer and connected to the front pads,
wherein upper surfaces of the bonding pads and an upper surface of the passivation layer are coplanar.

12. The wafer structure of claim 9, further comprising:
back pads on the second surface of the semiconductor substrate; and
through-electrodes extending from the first surface to the second surface of the semiconductor substrate and electrically connecting the front pads and the back pads.

13. The wafer structure of claim 12, further comprising a back passivation layer covering the second surface of the semiconductor substrate and exposing at least a portion of each of the back pads,
wherein lower surfaces of the back pads and a lower surface of the back passivation layer are coplanar.

14. The wafer structure of claim 1, wherein the interlayer insulating layer is composed of a material having a dielectric constant lower than a dielectric constant of a material forming the upper insulating layer.

15. The wafer structure of claim 14, wherein the interlayer insulating layer includes Silicon Oxyhydrocarbide (SiOCH) and silicon carbonitride (SiCN).

16. A wafer structure comprising:
a semiconductor substrate including chip regions and a scribe region between the chip regions;
a device layer disposed on the semiconductor substrate and the device layer including dummy structures within the scribe region;
a plurality of trenches disposed within the device layer and the plurality of trenches including a pair of trenches spaced apart from each other in a first direction and extending into a second direction which is perpendicular to the first direction within the scribe region and a central trench disposed between the pair of trenches and extending into the second direction; and
a passivation layer disposed on the device layer and filling at least a portion of each of the plurality of trenches,
wherein the dummy structures are positioned between the plurality of trenches.

17. The wafer structure of claim 16, wherein the dummy structures include a test pattern and an alignment key pattern.

18. The wafer structure of claim 16, wherein the device layer further includes a lower insulating layer, an interlayer insulating layer, and an upper insulating layer sequentially stacked on the semiconductor substrate,
wherein the lower insulating layer, the interlayer insulating layer, and the upper insulating layer respectively surround at least portions of the dummy structures, and the plurality of trenches penetrate the interlayer insulating layer.

19. The wafer structure of claim 18, wherein the interlayer insulating layer has a dielectric constant lower than dielectric constants of the lower insulating layer and the upper insulating layer.

20. A wafer structure comprising:
a semiconductor substrate including chip regions and a scribe region defining the chip regions;
a device layer including connection structures disposed within the chip regions, dummy structures within the scribe region, and an interlayer insulating layer surrounding the connection structures and the dummy structures; and
a plurality of trenches disposed within the scribe region and penetrating the interlayer insulating layer, wherein the plurality of trenches include a first trench and a second trench disposed along first and second sides of the scribe region respectively, and a third trench disposed between the first trench and the second trench, and the dummy structures are disposed between the plurality of trenches.
